(19) United States
(12) Patent Application Publication
(10) Pub. No.: US 2024/0105614 A1
(43) Pub. Date: Mar. 28, 2024

(54) TRANSISTORS WITH ENHANCED VIA-TO-BACKSIDE POWER RAIL

(71) Applicant: International Business Machines Corporation, Armonk, NY (US)

(72) Inventors: Ruilong Xie, Niskayuna, NY (US); Koichi Motoyama, Clifton Park, NY (US); Feng Liu, Niskayuna, NY (US)

(21) Appl. No.: 17/954,979

(22) Filed: Sep. 28, 2022

(51) Int. Cl. H01L 23/528; H01L 21/8238; H01L 27/092; H01L 29/06; H01L 29/417; H01L 29/423; H01L 29/66; H01L 29/775

(52) U.S. Cl. CPC H01L 23/5286; H01L 21/823871; H01L 27/092; H01L 29/0673; H01L 29/41733; H01L 29/42392; H01L 29/66439; H01L 29/775

(57) ABSTRACT

A semiconductor structure includes a first via-to-backside power rail having a lower portion and an upper portion. The lower portion is connected to a first backside power rail and has a first width and the upper portion has a second width less than the first width.

### BACKGROUND

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor FETs (MOSFETs). Complementary MOS (CMOS) devices are widely used, where both n-type and p-type transistors (nFET and pFET) are used to form logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

### SUMMARY

Illustrative embodiments of the present application include techniques for use in semiconductor manufacture. In one illustrative embodiment, a semiconductor structure comprises a first via-to-backside power rail having a lower portion and an upper portion. The lower portion is connected to a first backside power rail and has a first width and the upper portion has a second width less than the first width.

In another illustrative embodiment, a semiconductor structure comprises a first via-to-backside power rail having a lower portion, a middle portion and an upper portion, the lower portion disposed in an interlevel dielectric layer. The semiconductor structure further comprises a first backside power rail connected to the lower portion of the first via-to-backside power rail. The semiconductor structure further comprises a first source/drain region and a second source/drain region disposed on the interlevel dielectric layer. The lower portion has a first width and the middle portion has a second width less than the first width. The middle portion is disposed between the first source/drain region and the second source/drain region. The upper portion is disposed on a portion of a sidewall of the first source/drain region to connect the middle portion to the first source/drain region.

In yet another illustrative embodiment, a semiconductor structure comprises a via-to-backside power rail having a lower portion and an upper portion. The lower portion is connected to a backside power rail and has a first width and the upper portion has a second width less than the first width. The semiconductor structure further comprises a middle-of-the-line contact disposed on the upper portion of the via-to-backside power rail.

Other embodiments will be described in the following detailed description of embodiments, which is to be read in conjunction with the accompanying figures.

### BRIEF DESCRIPTION OF THE DRAWINGS

FIG. 1 is a cross sectional view illustrating a semiconductor structure for use at a first-intermediate fabrication stage, according to an illustrative embodiment.

FIG. 2A is a top view of a semiconductor structure at a second-intermediate fabrication stage, according to an illustrative embodiment.

FIG. 2B is a cross-sectional view of the semiconductor structure taken along the Y1-Y1 axis of FIG. 2A at the second-intermediate fabrication stage, according to an illustrative embodiment.

FIG. 3A is a top view of a semiconductor structure at a third-intermediate fabrication stage, according to an illustrative embodiment.

FIG. 3B is a cross-sectional view illustrating the semiconductor structure taken along the X1-X1 axis of FIG. 3A at the third-intermediate fabrication stage, according to an illustrative embodiment.

FIG. 3C is a cross-sectional view of the semiconductor structure taken along the X2-X2 axis of FIG. 3A at the third-intermediate fabrication stage, according to an illustrative embodiment.

FIG. 3D is a cross-sectional view of the semiconductor structure taken along the Y1-Y1 axis of FIG. 3A at the third-intermediate fabrication stage, according to an illustrative embodiment.

FIG. 3E is a cross-sectional view illustrating the semiconductor structure taken along the Y2-Y2 axis of FIG. 3A at the third-intermediate fabrication stage, according to an illustrative embodiment.

FIG. 4A is a top view of a semiconductor structure at a fourth-intermediate fabrication stage, according to an illustrative embodiment.

FIG. 4B is a cross-sectional view illustrating the semiconductor structure taken along the X1-X1 axis of FIG. 4A at the fourth-intermediate fabrication stage, according to an illustrative embodiment.

FIG. 4C is a cross-sectional view of the semiconductor structure taken along the X2-X2 axis of FIG. 4A at the fourth-intermediate fabrication stage, according to an illustrative embodiment.

FIG. 4D is a cross-sectional view of the semiconductor structure taken along the Y1-Y1 axis of FIG. 4A at the fourth-intermediate fabrication stage, according to an illustrative embodiment.

FIG. 4E is a cross-sectional view illustrating the semiconductor structure taken along the Y2-Y2 axis of FIG. 4A at the fourth-intermediate fabrication stage, according to an illustrative embodiment.

FIG. 5A is a top view of a semiconductor structure at a fifth-intermediate fabrication stage, according to an illustrative embodiment.

FIG. 5B is a cross-sectional view illustrating the semiconductor structure taken along the X1-X1 axis of FIG. 5A at the fifth-intermediate fabrication stage, according to an illustrative embodiment.

FIG. 5C is a cross-sectional view of the semiconductor structure taken along the X2-X2 axis of FIG. 5A at the fifth-intermediate fabrication stage, according to an illustrative embodiment.

FIG. 5D is a cross-sectional view of the semiconductor structure taken along the Y1-Y1 axis of FIG. 5A at the fifth-intermediate fabrication stage, according to an illustrative embodiment.

FIG. 5E is a cross-sectional view illustrating the semiconductor structure taken along the Y2-Y2 axis of FIG. 5A at the fifth-intermediate fabrication stage, according to an illustrative embodiment.

FIG. 6A is a top view of a semiconductor structure at a sixth-intermediate fabrication stage, according to an illustrative embodiment.

FIG. 6B is a cross-sectional view illustrating the semiconductor structure taken along the X1-X1 axis of FIG. 6A at the sixth-intermediate fabrication stage, according to an illustrative embodiment.

FIG. 6C is a cross-sectional view of the semiconductor structure taken along the X2-X2 axis of FIG. 6A at the sixth-intermediate fabrication stage, according to an illustrative embodiment.

FIG. 6D is a cross-sectional view of the semiconductor structure taken along the Y1-Y1 axis of FIG. 6A at the sixth-intermediate fabrication stage, according to an illustrative embodiment.

FIG. 6E is a cross-sectional view illustrating the semiconductor structure taken along the Y2-Y2 axis of FIG. 6A at the sixth-intermediate fabrication stage, according to an illustrative embodiment.

FIG. 7A is a cross-sectional view illustrating the semiconductor structure taken along the X1-X1 axis of FIG. 6A at a seventh-intermediate fabrication stage, according to an illustrative embodiment.

FIG. 7B is a cross-sectional view of the semiconductor structure taken along the X2-X2 axis of FIG. 6A at the seventh-intermediate fabrication stage, according to an illustrative embodiment.

FIG. 7C is a cross-sectional view of the semiconductor structure taken along the Y1-Y1 axis of FIG. 6A at the seventh-intermediate fabrication stage, according to an illustrative embodiment.

FIG. 7D is a cross-sectional view illustrating the semiconductor structure taken along the Y2-Y2 axis of FIG. 6A at the seventh-intermediate fabrication stage, according to an illustrative embodiment.

FIG. 8A is a cross-sectional view illustrating the semiconductor structure taken along the X1-X1 axis of FIG. 6A at an eighth-intermediate fabrication stage, according to an illustrative embodiment.

FIG. 8B is a cross-sectional view of the semiconductor structure taken along the X2-X2 axis of FIG. 6A at the eighth-intermediate fabrication stage, according to an illustrative embodiment.

FIG. 8C is a cross-sectional view of the semiconductor structure taken along the Y1-Y1 axis of FIG. 6A at the eighth-intermediate fabrication stage, according to an illustrative embodiment.

FIG. 8D is a cross-sectional view illustrating the semiconductor structure taken along the Y2-Y2 axis of FIG. 6A at the eighth-intermediate fabrication stage, according to an illustrative embodiment.

FIG. 9A is a cross-sectional view illustrating the semiconductor structure taken along the X1-X1 axis of FIG. 6A at a ninth-intermediate fabrication stage, according to an illustrative embodiment.

FIG. 9B is a cross-sectional view of the semiconductor structure taken along the X2-X2 axis of FIG. 6A at the ninth-intermediate fabrication stage, according to an illustrative embodiment.

FIG. 9C is a cross-sectional view of the semiconductor structure taken along the Y1-Y1 axis of FIG. 6A at the ninth-intermediate fabrication stage, according to an illustrative embodiment.

FIG. 9D is a cross-sectional view illustrating the semiconductor structure taken along the Y2-Y2 axis of FIG. 6A at the ninth-intermediate fabrication stage, according to an illustrative embodiment.

FIG. 10A is a top view of a semiconductor structure at a tenth-intermediate fabrication stage, according to an illustrative embodiment.

FIG. 10B is a cross-sectional view illustrating the semiconductor structure taken along the X1-X1 axis of FIG. 10A at the tenth-intermediate fabrication stage, according to an illustrative embodiment.

FIG. 10C is a cross-sectional view of the semiconductor structure taken along the X2-X2 axis of FIG. 10A at the tenth-intermediate fabrication stage, according to an illustrative embodiment.

FIG. 10D is a cross-sectional view of the semiconductor structure taken along the Y1-Y1 axis of FIG. 10A at the tenth-intermediate fabrication stage, according to an illustrative embodiment.

FIG. 10E is a cross-sectional view illustrating the semiconductor structure taken along the Y2-Y2 axis of FIG. 10A at the tenth-intermediate fabrication stage, according to an illustrative embodiment.

FIG. 11A is a cross-sectional view illustrating the semiconductor structure taken along the X1-X1 axis of FIG. 10A at an eleventh-intermediate fabrication stage, according to an illustrative embodiment.

FIG. 11B is a cross-sectional view of the semiconductor structure taken along the X2-X2 axis of FIG. 10A at the eleventh-intermediate fabrication stage, according to an illustrative embodiment.

FIG. 11C is a cross-sectional view of the semiconductor structure taken along the Y1-Y1 axis of FIG. 10A at the eleventh-intermediate fabrication stage, according to an illustrative embodiment.

FIG. 11D is a cross-sectional view illustrating the semiconductor structure taken along the Y2-Y2 axis of FIG. 10A at the eleventh-intermediate fabrication stage, according to an illustrative embodiment.

FIG. 12A is a cross-sectional view illustrating the semiconductor structure taken along the X1-X1 axis of FIG. 10A at a twelfth-intermediate fabrication stage, according to an illustrative embodiment.

FIG. 12B is a cross-sectional view of the semiconductor structure taken along the X2-X2 axis of FIG. 10A at the twelfth-intermediate fabrication stage, according to an illustrative embodiment.

FIG. 12C is a cross-sectional view of the semiconductor structure taken along the Y1-Y1 axis of FIG. 10A at the twelfth-intermediate fabrication stage, according to an illustrative embodiment.

FIG. 12D is a cross-sectional view illustrating the semiconductor structure taken along the Y2-Y2 axis of FIG. 10A at the twelfth-intermediate fabrication stage, according to an illustrative embodiment.

FIG. 13A is a cross-sectional view illustrating the semiconductor structure taken along the X1-X1 axis of FIG. 10A at a thirteenth-intermediate fabrication stage, according to an illustrative embodiment.

FIG. 13B is a cross-sectional view of the semiconductor structure taken along the X2-X2 axis of FIG. 10A at the thirteenth-intermediate fabrication stage, according to an illustrative embodiment.

FIG. 13C is a cross-sectional view of the semiconductor structure taken along the Y1-Y1 axis of FIG. 10A at the thirteenth-intermediate fabrication stage, according to an illustrative embodiment.

FIG. 13D is a cross-sectional view illustrating the semiconductor structure taken along the Y2-Y2 axis of FIG. 10A at the thirteenth-intermediate fabrication stage, according to an illustrative embodiment.

FIG. 14A is a cross-sectional view illustrating the semiconductor structure taken along the X1-X1 axis of FIG. 10A at a fourteenth-intermediate fabrication stage, according to an illustrative embodiment.

FIG. 14B is a cross-sectional view of the semiconductor structure taken along the X2-X2 axis of FIG. 10A at the fourteenth-intermediate fabrication stage, according to an illustrative embodiment.

FIG. 14C is a cross-sectional view of the semiconductor structure taken along the Y1-Y1 axis of FIG. 10A at the fourteenth-intermediate fabrication stage, according to an illustrative embodiment.

FIG. 14D is a cross-sectional view illustrating the semiconductor structure taken along the Y2-Y2 axis of FIG. 10A at the fourteenth-intermediate fabrication stage, according to an illustrative embodiment.

### DETAILED DESCRIPTION

Illustrative embodiments of the invention may be described herein in the context of illustrative methods for forming isolation pillar structures in stacked device structures to prevent shorting between contacts, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the IC chip fabrication industry, there are three sections referred to in a typical IC chip build: front-end-of-line (FEOL), back-end-of-line (BEOL), and the section that connects those two together, the middle-of-the-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

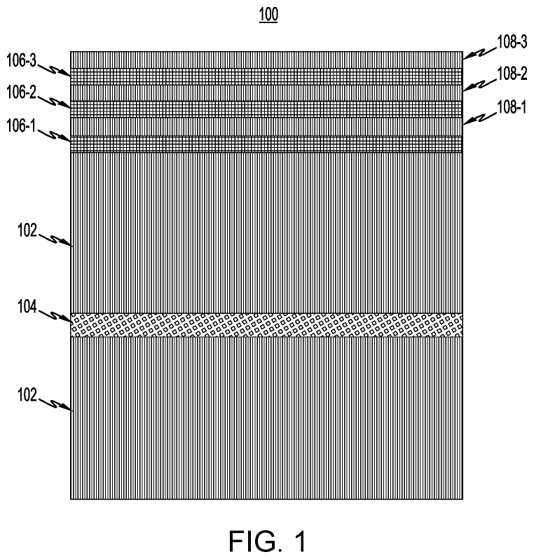

Present semiconductor processing forms a frontside via-to-backside power rail in which the via-to-backside power rail connection may be too weak as a high resistance path. For example, the height of the frontside via-to-backside power rail size formed is relatively tall with a narrow width, which can result in a resistance bottleneck. Illustrative embodiments provide methods and structures for overcoming the foregoing drawbacks by forming a portion of a frontside via-to-backside power rail disposed on a backside power rail having a width greater than a width of another portion of the via-to-backside power rail that is not disposed on the backside power rail. Referring now to FIGS. 1-14D, FIG. 1 shows a semiconductor structure 100 having substrate 102 and etch stop layer 104 formed in the substrate 102. The substrate 102 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, substrate 102 is silicon. The etch stop layer 104 may comprise a buried oxide (BOX) layer or silicon germanium (SiGe), or another suitable material such as a III-V semiconductor epitaxial layer.

Nanosheets are formed over the substrate 102, where the nanosheets include sacrificial layers 106-1, 106-2 and 106-3 (collectively, sacrificial layers 106), and nanosheet channel layers 108-1, 108-2 and 108-3 (collectively, nanosheet channel layers 108).

The sacrificial layers 106 are illustratively formed of a sacrificial material, such that they may be etched or otherwise removed selectively. In some embodiments, the sacrificial layers 106 are formed of SiGe. For example, the sacrificial layers 106 may have a relatively higher percentage of Ge (e.g., 55% Ge) or a relatively lower percentage of Ge (e.g., 25% Ge).

The nanosheet channel layers 108 may be formed of Si or another suitable material (e.g., a material similar to that used for the substrate 102).

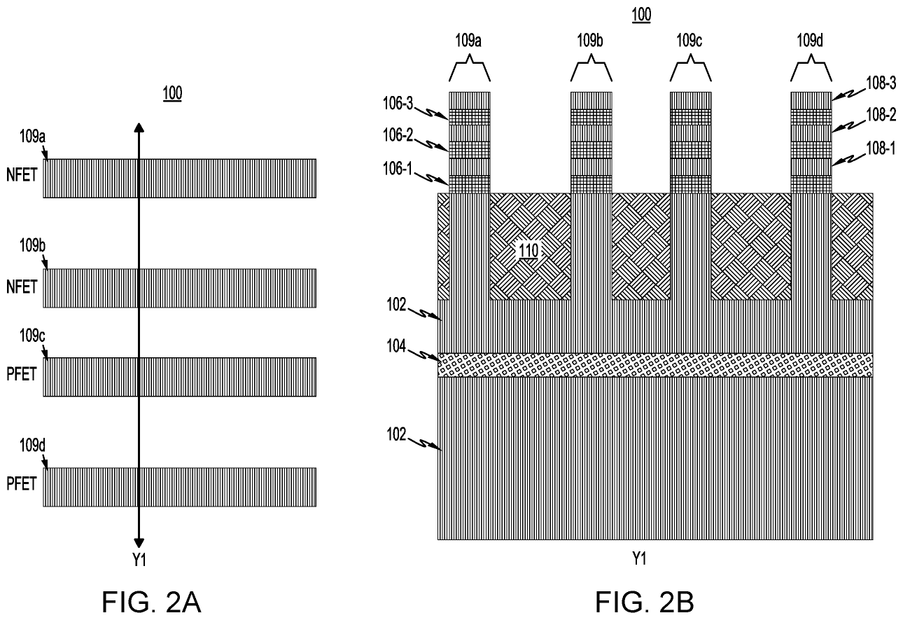

FIGS. 2A and 2B show a semiconductor structure 100 at a second-intermediate fabrication stage. During this stage, nanosheet patterning and formation of FET stacks 109a, 109b, 109c and 109d together with shallow trench isolation (STI) regions 110 are carried out. Each of FET stacks 109a, 109b, 109c and 109d contain a respective FET device. However, this is merely illustrative and it is contemplated that FET stacks 109a, 109b, 109c and 109d can contain any number of FET devices. The first ones of FET stacks 109a and 109b may comprise nFET devices and the second ones of FET stacks 109c and 109d may comprise pFET devices.

The STI regions 110 may be formed by patterning a masking layer over the semiconductor structure 100, followed by etching exposed portions of the nanosheet channel layers 108, the sacrificial layers 106, and through a portion of the substrate 102. The STI regions 110 may be formed of a dielectric material such as silicon dioxide (SiO₂), silicon oxycarbide (SiOC), silicon oxynitride (SiON), etc.

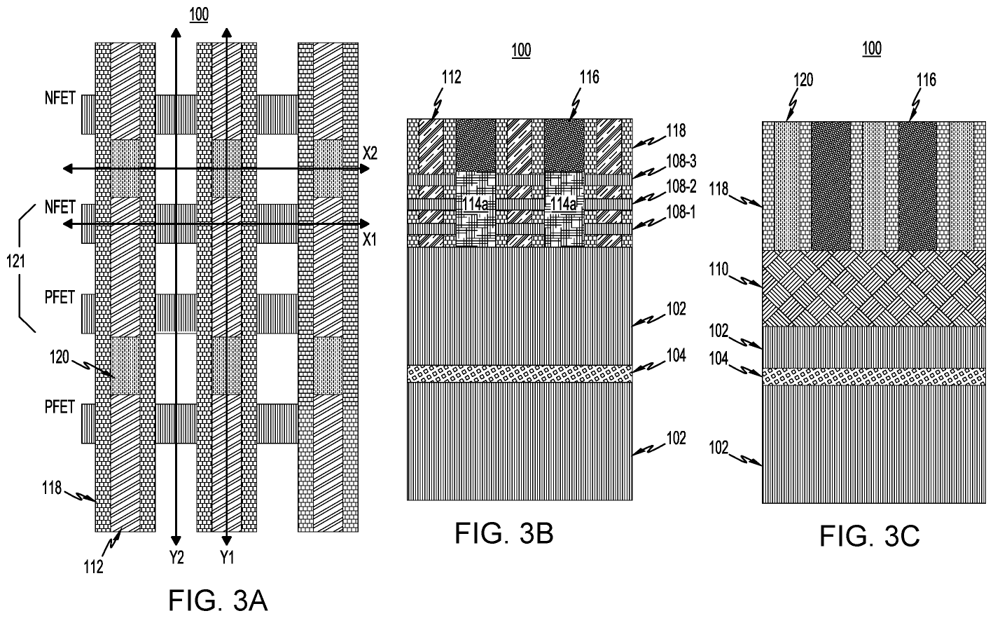

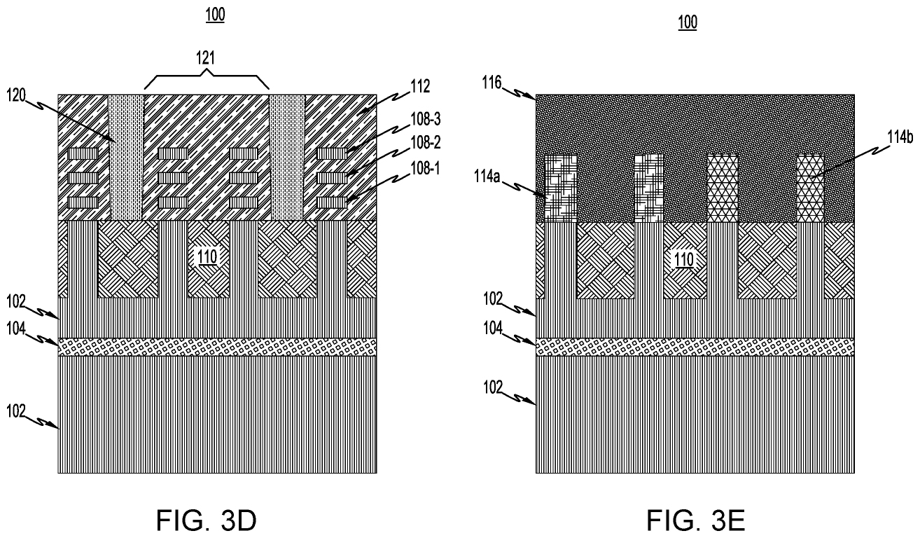

FIGS. 3A-3E show semiconductor structure 100 at a third-intermediate fabrication stage. During this stage, processing of the structure includes forming a gate stack layer 112, source/drain regions 114a and 114b, an interlayer dielectric (ILD) layer 116, sidewall spacers 118 and dielectric pillars 120. To form the structure shown in FIGS. 3B and 3D, dummy gates are first formed over the nanosheets, followed by sidewall spacer 118 formation by conformal dielectric liner deposition and anisotropic dielectric liner etching. Next, the source/drain regions 114a and 114b and ILD layer 116 are formed, followed by poly open CMP, dielectric pillars 120 formation, and removal of the dummy gates and sacrificial layers 106. Following removal of the dummy gates, the gate stack layer 112 is formed (e.g., using replacement high-k metal gate (HKMG) processing).

The gate stack layer 112 may comprise a gate dielectric layer and a gate conductor layer. The gate dielectric layer may be formed of a high-k dielectric material. Examples of high-k dielectric materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k material may further include dopants such as lanthanum (La), aluminum (Al), and magnesium (Mg). The gate dielectric layer may have a uniform thickness in the range of 1 nm to 3 nm.

The gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

The ILD layer 116 is formed on the source/drain regions 114a and 114b and over the top of the STI region 110 by conventional deposition processes such as physical vapor deposition (PVD), atomic layer deposition (ALD), chemical vapor deposition (CVD) and/or plating. The ILD layer 116 may be formed of any suitable isolating material, such as SiO₂, SiOC, SiON, etc.

The source/drain regions 114a and 114b may be formed using epitaxial growth processes. The source/drain regions 114a and 114b may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). In illustrative embodiments, FIG. 3B shows semiconductor structure 100 having source/drain regions 114a and 114b which are n-type source/drain regions and FIG. 3E shows semiconductor structure having source/drain regions 114a and 114b which are n-type source/drain regions and source/drain regions 114a and 114b which are p-type source/drain regions. However, this is merely illustrative and other arrangements are contemplated herein.

The source/drain regions 114a and 114b may be formed using epitaxial growth processes. In some embodiments, the epitaxy process comprises in-situ doping (dopants are incorporated in epitaxy material during epitaxy). Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×10²⁰ cm⁻³ to 3×10²¹ cm⁻³.

The sidewall spacers 118 may be formed of any suitable insulator, such as SiN, silicon boron carbide nitride (SiBCN), silicon oxycarbonitride (SiOCN), etc.

A gate cut is performed in semiconductor structure 100 by conventional techniques to form an opening (not shown) which stops on the STI regions 110. Next, a dielectric fill is deposited in the opening and fills the opening to form dielectric pillars 120. The dielectric pillars 120 may be formed by filling a dielectric material such as, for example, SiN, SiO₂, SiOC, SiOCN, SiBCN, SiC, etc. in the opening, followed by planarization using chemical mechanical planarization (CMP) or other suitable planarization process. In illustrative embodiments, FIG. 3B shows dielectric pillars 120 formed in ILD layer 116. In other illustrative embodiments, FIG. 3D shows dielectric pillars 120 formed in gate stack layer 112 to form a FET cell having an NFET region and a PFET region.

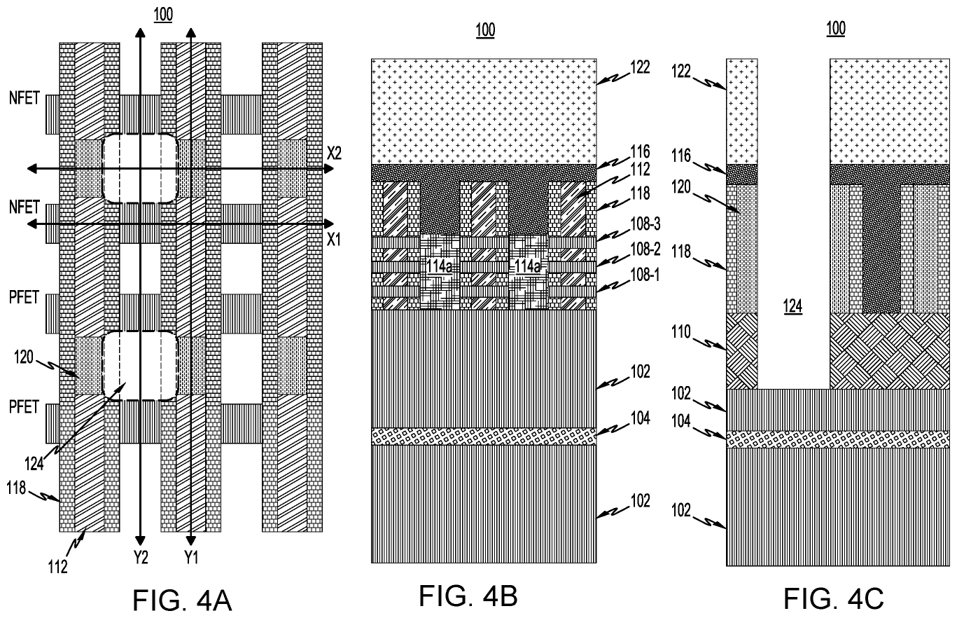

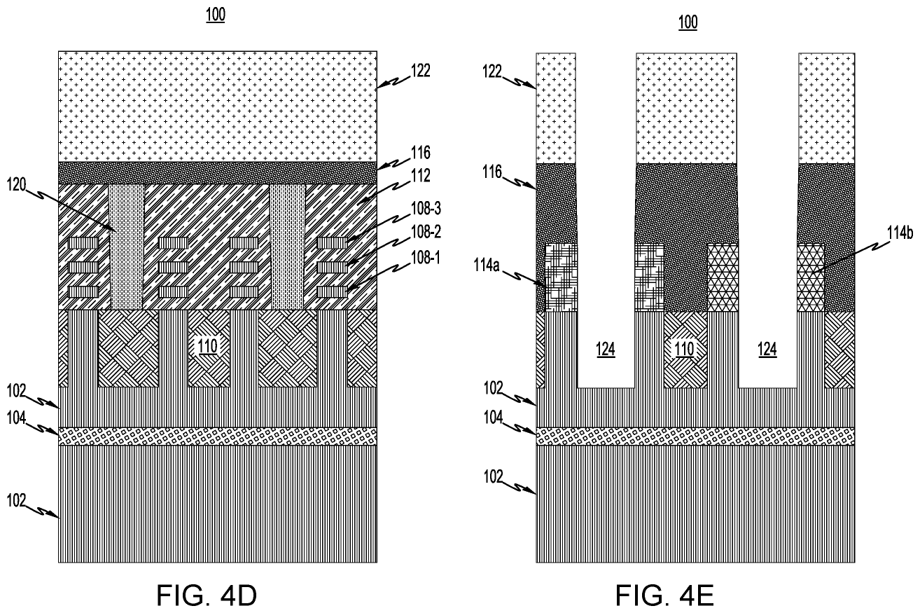

FIGS. 4A-4E show semiconductor structure 100 at a fourth-intermediate fabrication stage. During this stage, via-to-backside power rail (VBPR) opening 124 is formed by first depositing an additional ILD layer 116 on top of semiconductor structure 100, followed by depositing a mask layer 122 (such as an organic planarization layer (OPL) on ILD layer 116 using any conventional deposition process such as PVD, ALD and CVD. Mask layer 122 can be composed of a flowable organic material such as, for example, a spin-on-carbon (SOC). Next, the mask layer 122 is patterned and then selectively etched to form VBPR opening 124.

FIG. 4C shows semiconductor structure 100 after removal of portions of mask layer 122, ILD layer 116, dielectric pillars 120, and STI region 110 by, for example, reactive-ion etching (RIE) or other suitable etch processing to form VBPR opening 124.

FIG. 4E shows semiconductor structure 100 after removal of portions of mask layer 122, ILD layer 116, and STI region 110 by, for example, RIE or other suitable etch processing to form VBPR opening 124.

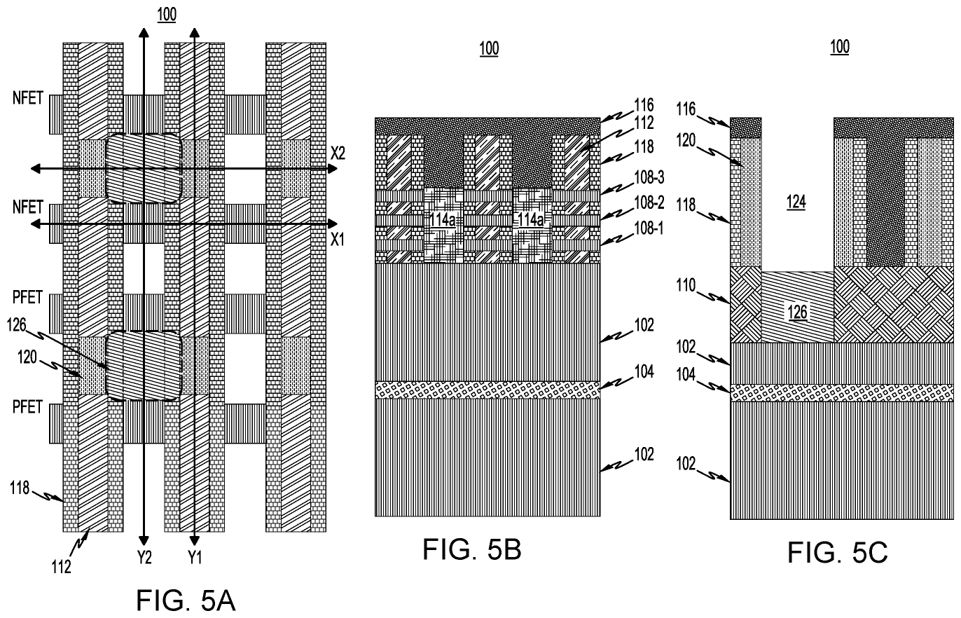

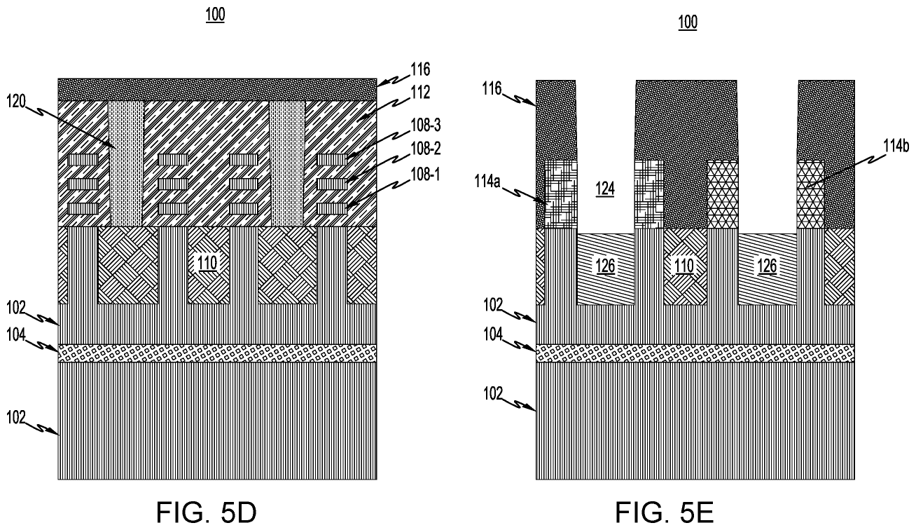

FIGS. 5A-5E show semiconductor structure 100 at a fifth-intermediate fabrication stage. During this stage, mask layer 122 is removed and a conductive metal is deposited in a portion of each VBPR opening 124 to form a first and a second lower portion VBPR 126 (collectively, lower portion VBPR 126). Mask layer 122 is removed by anisotropic dry or wet etching. The conductive metal is deposited by conventional deposition processes such as PVD, ALD, CVD, and/or plating. Suitable conductive metals include, for example, conductive material such as, for example, tungsten (W), aluminum (Al), copper (Cu), cobalt (Co), ruthenium (Ru), molybdenum (Mo), or any other suitable conductive material. In illustrative embodiments, lower portion VBPR 126 can have a width ranging from about 20 to about 100 nanometers (nm).

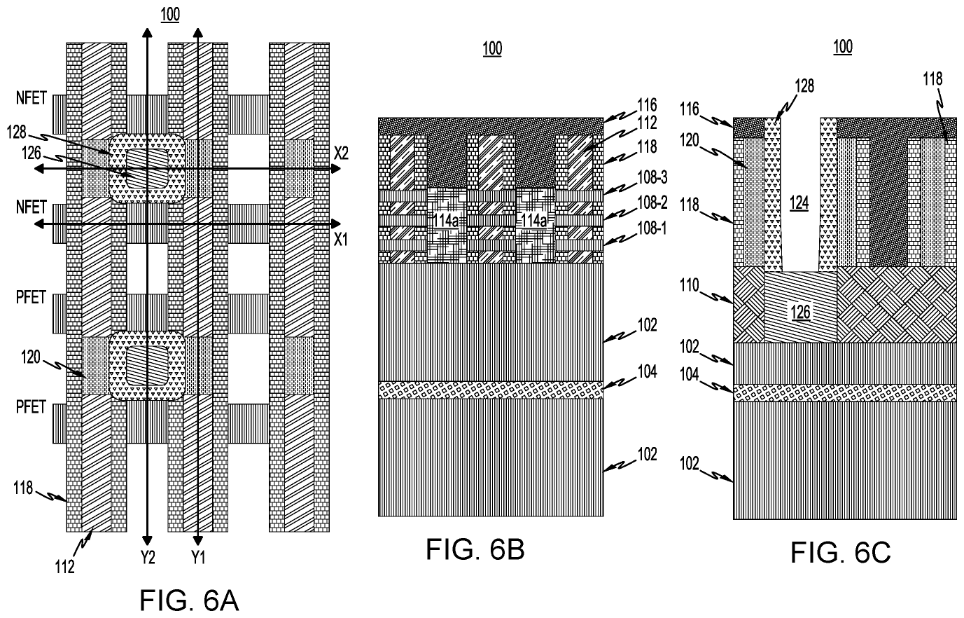

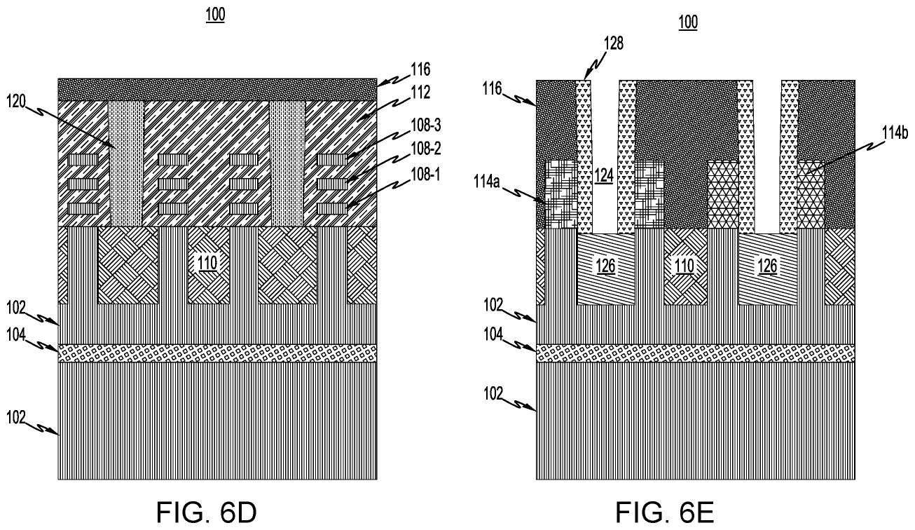

FIGS. 6A-6E show semiconductor structure 100 at a sixth-intermediate fabrication stage. During this stage, a self-aligned dielectric spacer 128 is formed on sidewalls of the remaining portion of VBPR opening 124 to separate the middle portion VBPR as discussed below from source/drain regions 114a and 114b and dielectric pillars 120. The self-aligned dielectric spacer 128 is formed by conventional deposition processes such as PVD, ALD, CVD, and/or plating. Suitable material for self-aligned dielectric spacer 128 includes, for example, a dielectric material such as SiN, SiO₂, SiOC, SiOCN, SiBCN, SiC, etc.

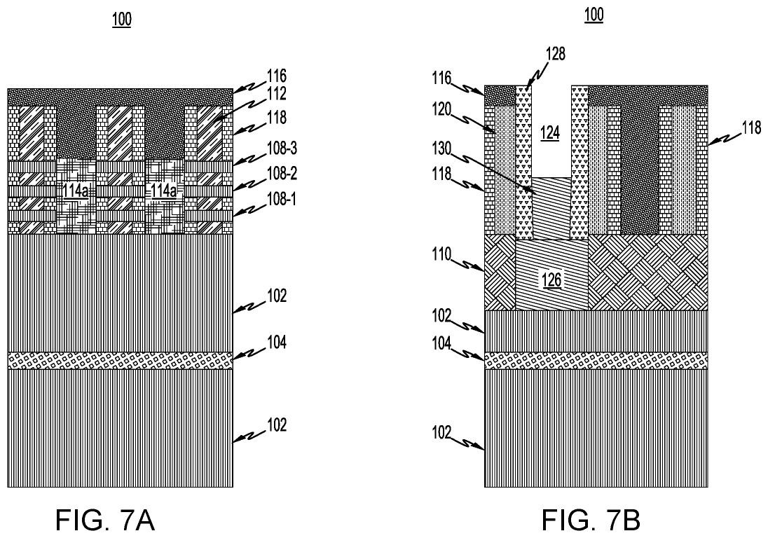

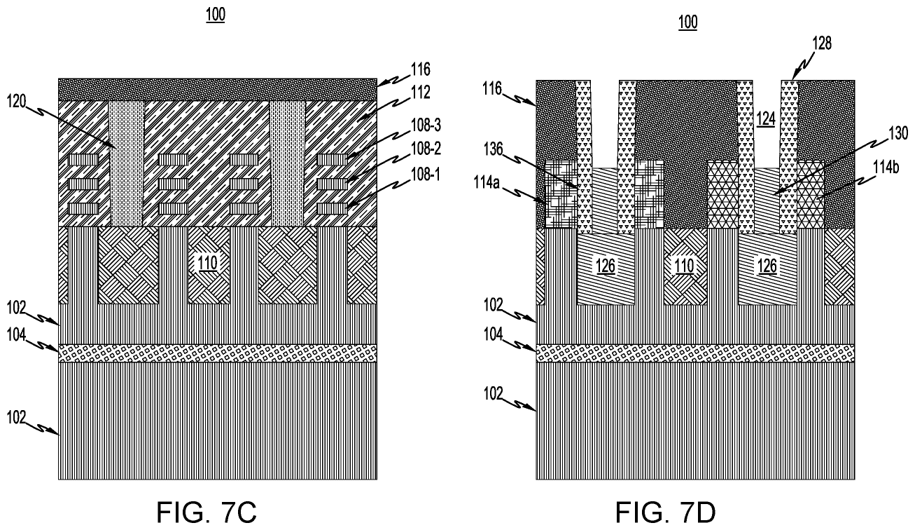

FIGS. 7A-7D show semiconductor structure 100 at a seventh-intermediate fabrication stage. During this stage, a conductive metal is formed in another portion of each VBPR opening 124 and on lower portion VBPR 126 to form a first and a second middle portion VBPR 130 (collectively, middle portion VBPR 130). The conductive metal is deposited by conventional deposition processes such as PVD, ALD, CVD, and/or plating. Alternatively, it can be a bottom up selective metal growth process from the lower portion VBPR 126. The conductive metal can be any of those discussed above. In illustrative embodiments, middle portion VBPR 130 can have a width ranging from about 10 to about 90 nm.

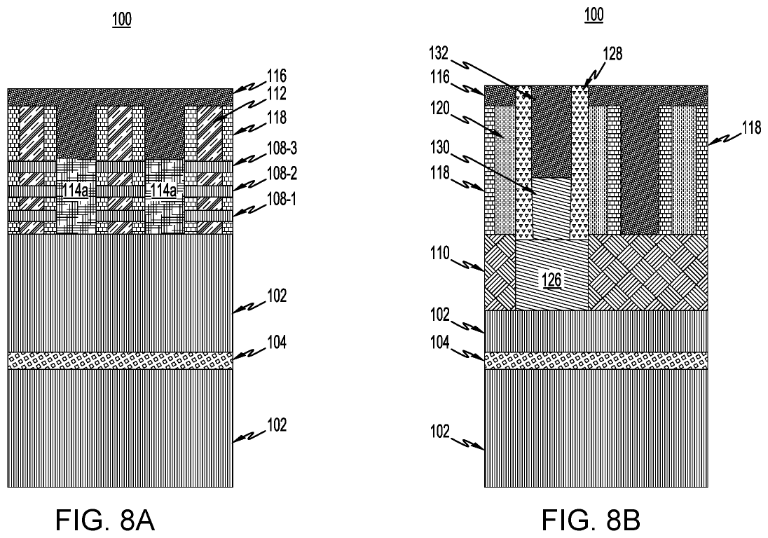

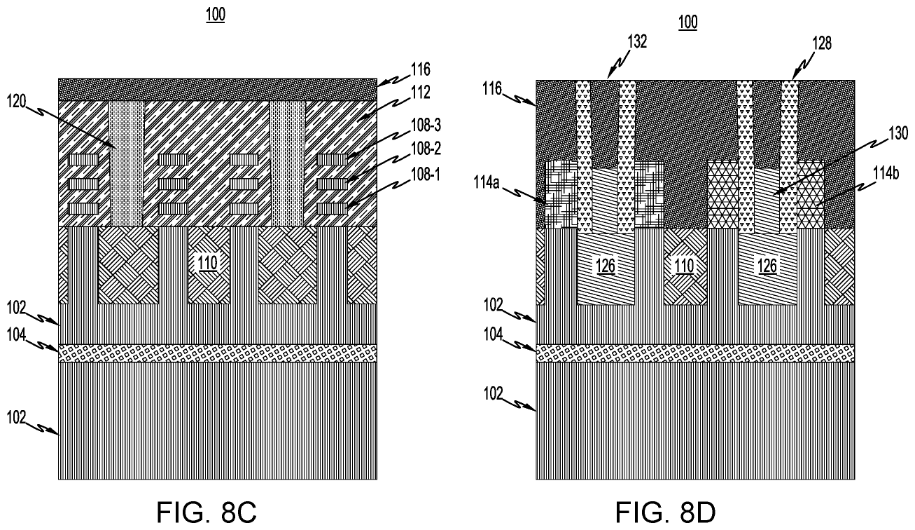

FIGS. 8A-8D show semiconductor structure 100 at an eighth-intermediate fabrication stage. During this stage, ILD layer 132 is deposited in the remaining portion of VBPR opening 124 followed by planarization using such as chemical mechanical planarization (CMP) or other suitable planarization process. The ILD layer 132 is deposited by conventional deposition processes such as PVD, ALD, CVD, and/or plating. The ILD layer 132 can be any of the material discussed above for ILD layer 116.

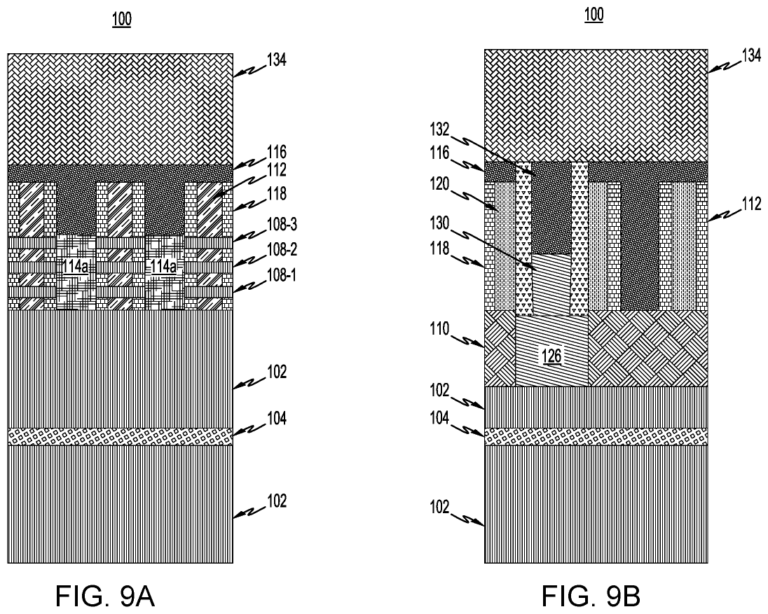

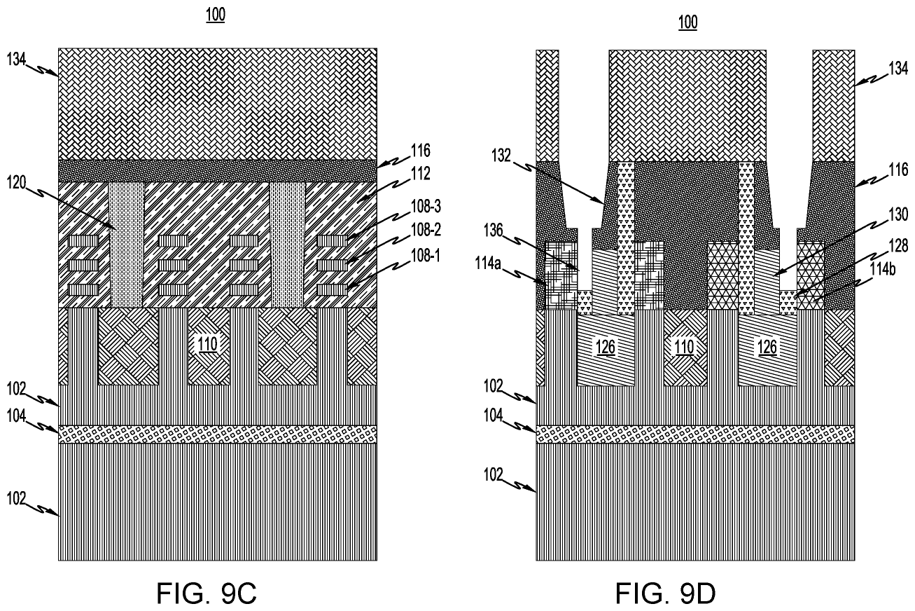

FIGS. 9A-9D show semiconductor structure 100 at a ninth-intermediate fabrication stage. During this stage, mask layer 134 (such as an OPL), is deposited over the semiconductor structure 100 followed conventional lithographic patterning and etching process. The mask layer 134 is deposited using similar processes and material as discussed above for mask layer 122. Next, a top portion VBPR opening 136 is formed by patterning and then selectively etching mask layer 134. In illustrative embodiments, FIG. 9D shows semiconductor structure 100 after selective removal of portions of mask layer 134, ILD layer 132, self-aligned dielectric spacer 128 and ILD layer 116 by, for example, RIE or other suitable etch processing.

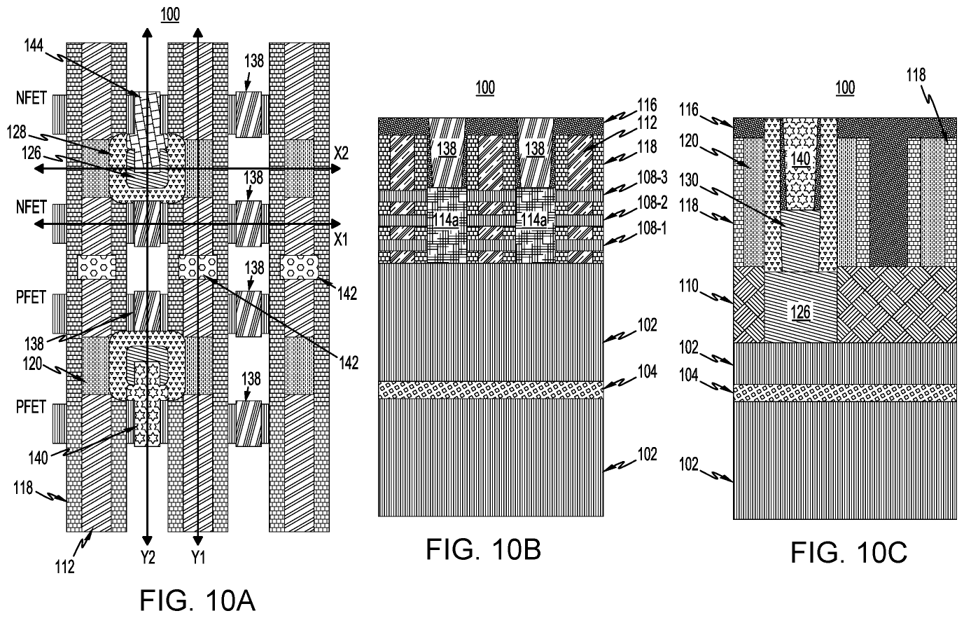

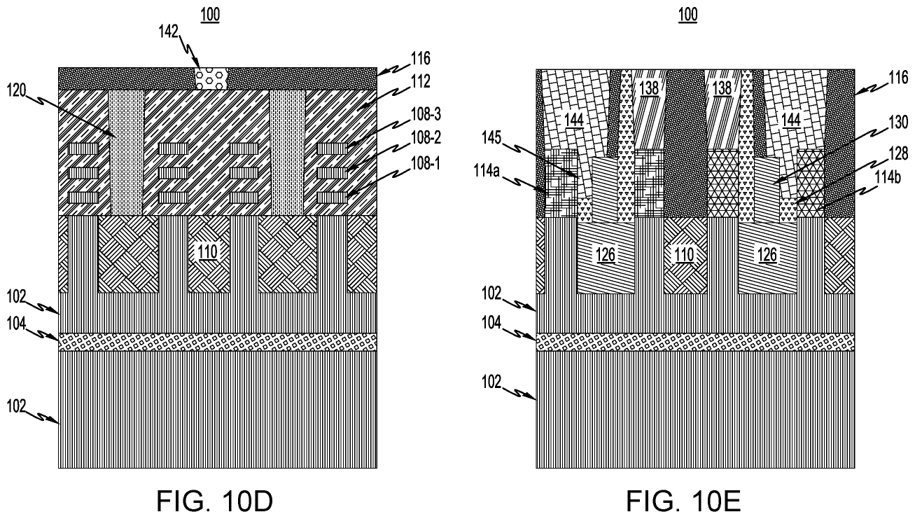

FIG. 10A-10E show semiconductor structure 100 at a tenth-intermediate fabrication stage following the formation of the middle-of-the-line contacts (MOL). In illustrative embodiments, FIG. 10B shows formation of source/drain contacts 138. In illustrative embodiments, FIG. 10C shows formation of middle-of-the-line contact 140 disposed on middle portion VBPR 130. In illustrative embodiments, FIG. 10D shows formation of gate contacts 142. In illustrative embodiments, FIG. 10E shows formation of source/drain contacts 138 and middle-of-the-line contacts 144 disposed on top portion VBPR 145.

Formation of the MOL contacts includes formation of source/drain contacts 138, middle-of-the-line contact 140 and gate contacts 142 by any conventional technique. For example, source/drain contacts 138, middle-of-the-line contact 140 and the gate contacts 142 can be formed utilizing conventional lithographic and etching processes in at least mask layer 134 and ILD layer 132 to form a via. Next, a conductive metal is deposited in the vias to form source/drain contacts 138, middle-of-the-line contact 140 and the gate contacts 142. Suitable conductive metals can be any of those discussed above. In various embodiments, the conductive metal can be deposited by ALD, CVD, PVD, and/or plating. The high conductance metal can be planarized using, for example, a planarizing process such as CMP. Other planarization processes can include grinding and polishing.

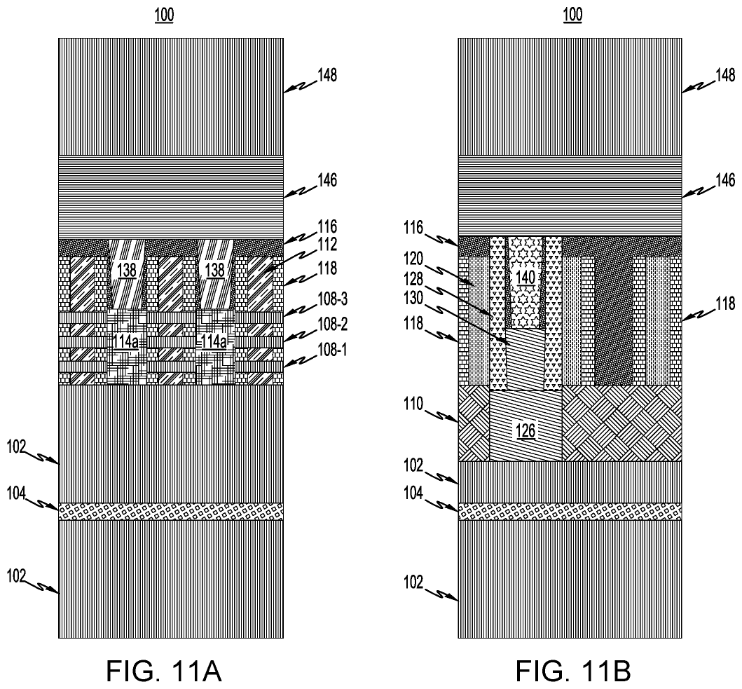

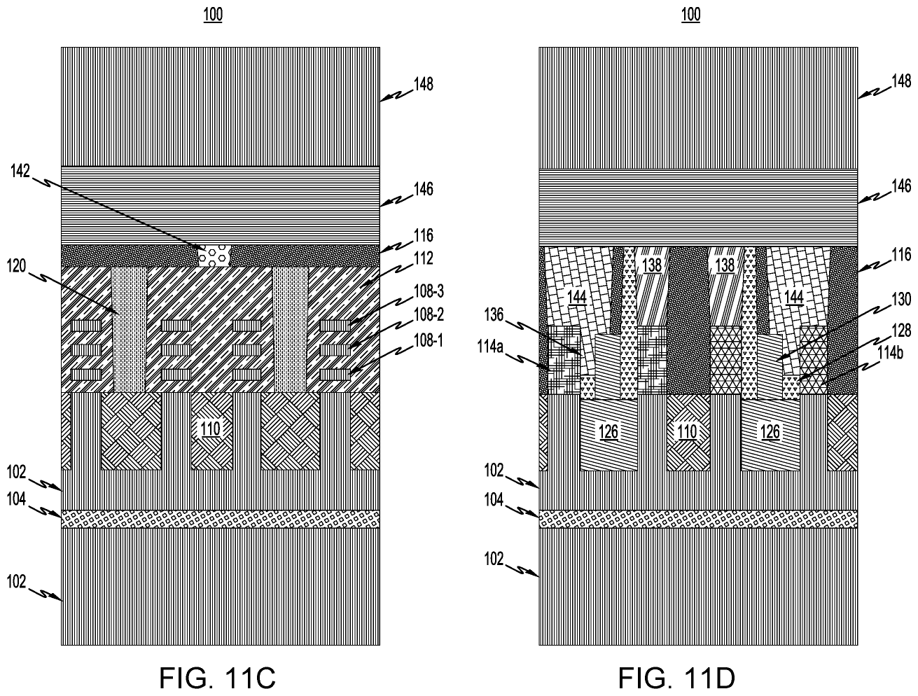

FIGS. 11A-11D illustrate semiconductor structure 100 at an eleventh-intermediate fabrication stage. During this stage, frontside back-end-of-line (BEOL) interconnect 146 is formed followed by bonding of the structure (e.g., the frontside BEOL interconnect 146) to a carrier wafer 148. The frontside BEOL interconnect 146 includes various BEOL interconnect structures. For example, frontside BEOL interconnect 146 is a metallization structure that includes one or more metal layers disposed on a side of semiconductor structure 100 opposite of the side on which the backside BEOL metallization structure is disposed. The metal layers of the frontside BEOL interconnect 146 each have metal lines for making interconnections to the semiconductor device.

The carrier wafer 148 may be formed of materials similar to that of the substrate 102, and may be formed over the frontside BEOL interconnect 146 using a wafer bonding process, such as dielectric-to-dielectric bonding.

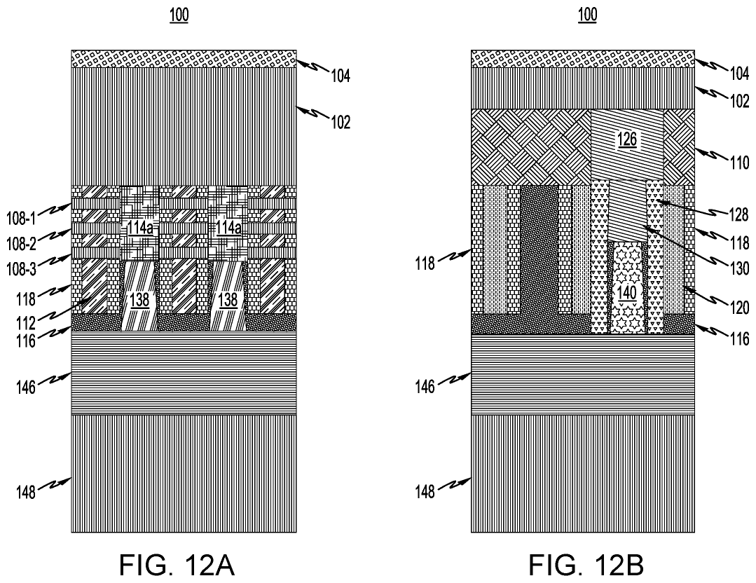

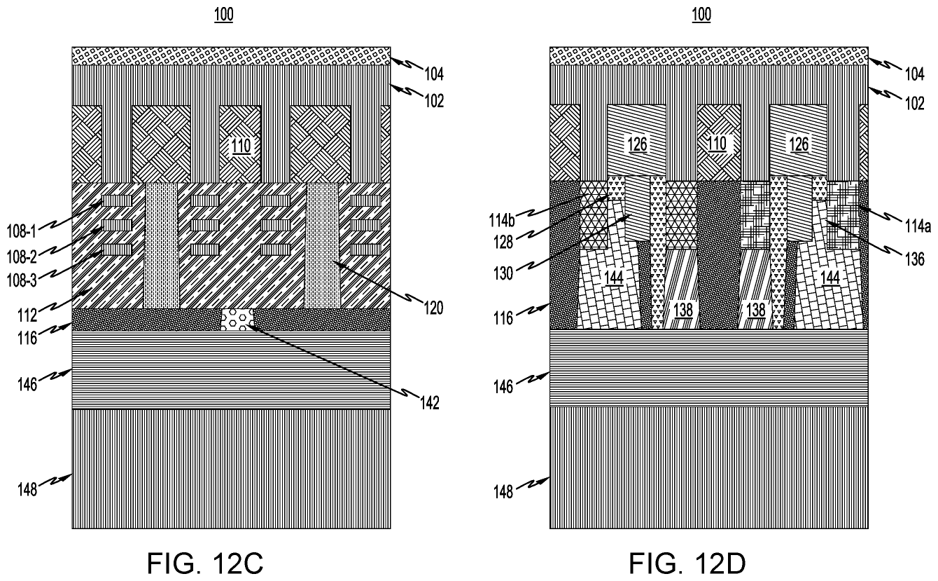

FIGS. 12A-12D illustrate semiconductor structure 100 at a twelfth-intermediate fabrication stage. During this stage, using the carrier wafer 148, the structure is “flipped” over so that the backside of the substrate 102 (i.e., the back surface) is facing up for backside processing as shown. Next, portions of the substrate 102 may be removed from the backside using, for example, a wet etch to selectively remove substrate 102 until the etch stop layer 104 is reached.

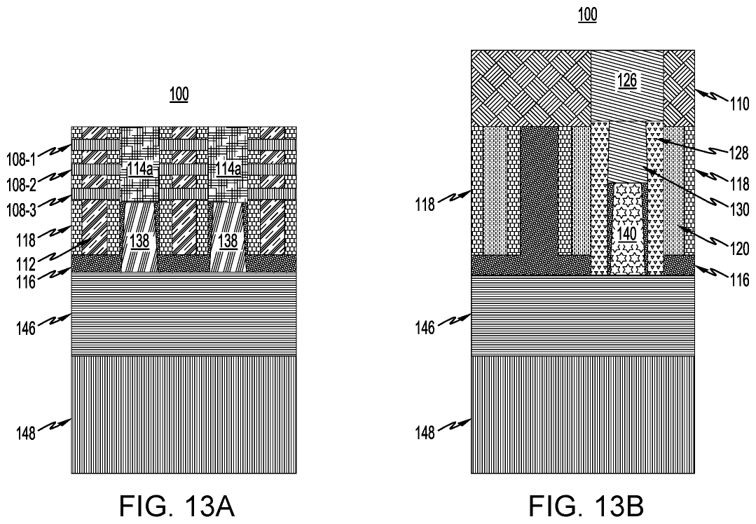

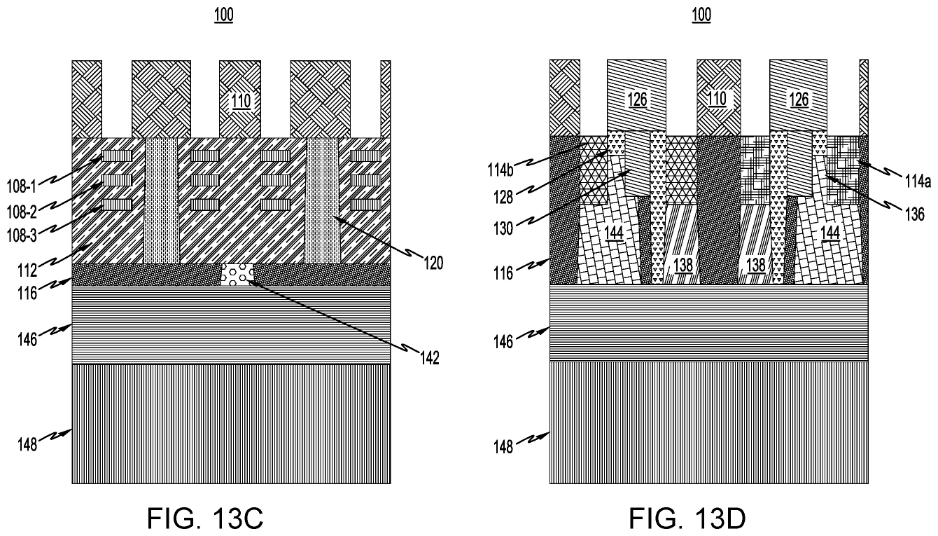

FIGS. 13A-13D illustrate semiconductor structure 100 at a thirteenth-intermediate fabrication stage. During this stage, the etch stop layer 104 is selectively removed using, for example, a wet etch to selectively remove etch stop layer 104 until substrate 102 is reached. The remaining portions of the substrate 102 are removed utilizing a selective etch process such as a wet etch.

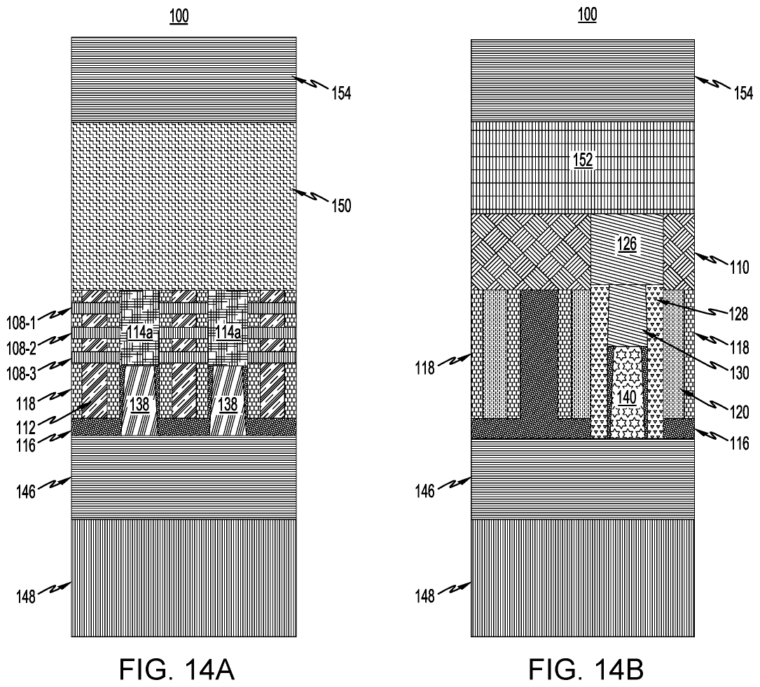

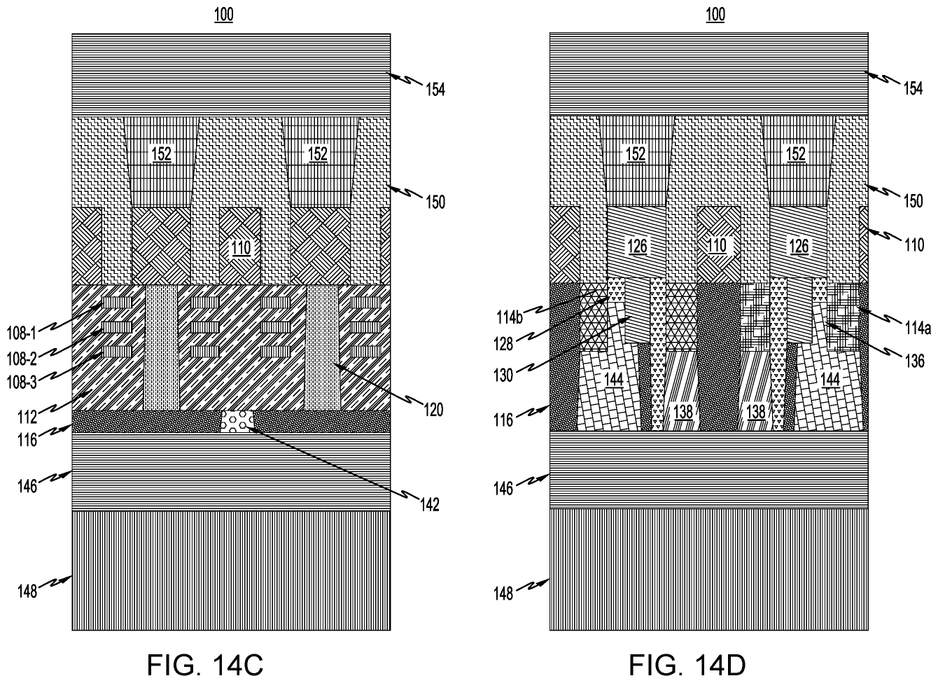

FIGS. 14A-14D illustrate semiconductor structure 100 at a fourteenth-intermediate fabrication stage. During this stage, backside ILD layer 150 may be formed of similar processes and material as ILD layer 116. The material of the backside ILD layer 150 may initially be overfilled, followed by planarization (e.g., using CMP). Next, backside power rail 152 is formed in backside ILD layer 150 by first patterning and etching vias in the exposed backside ILD layer 150. A suitable conductive metal is then deposited in the vias and on top of backside ILD layer 150, followed by CMP to remove any metal on top of backside ILD layer 150. A suitable conductive metal can be any of the metals discussed above.

In illustrative embodiments, FIG. 14B shows lower portion VBPR 126 disposed in STI region 110 and a middle portion VBPR 130 disposed on lower portion VBPR 126, with middle portion VBPR 130 having a width less than a width of lower portion VBPR 126. FIG. 14B further shows middle-of-the-line contact 140 disposed on middle portion VBPR 130 and being separated from middle portion VBPR 130 by self-aligned dielectric spacer 128. FIG. 14B further shows dielectric pillars 120 disposed on self-aligned dielectric spacer 128. FIG. 14B further shows frontside BEOL interconnect 146 disposed on the middle-of-the-line contact 140.

In illustrative embodiments, FIG. 14D shows a first and a second lower portion VBPR 126 disposed in backside ILD layer 150 and a first and a second middle portion VBPR 130 disposed on first and a second lower portion VBPR 126, respectively, with each middle portion VBPR 130 having a width less than a width of lower portion VBPR 126. The first and second lower portion VBPR 126 are disposed on backside power rail 152. FIG. 14D further shows source/drain regions 114a and 114b disposed on both sides of respective middle portion VBPR 130 and being separated from middle portion VBPR 130 by self-aligned dielectric spacer 128. In illustrative embodiments, source/drain regions 114a disposed on both sides of a given middle portion VBPR 130 are an n-type region and source/drain regions 114b disposed on both sides of the other middle portion VBPR 130 are a p-type region. FIG. 14D further shows source/drain regions 114a and 114b disposed on backside ILD layer 150.

In illustrative embodiments, FIG. 14D shows a first and a second lower portion VBPR 126 disposed in backside ILD layer 150 and a first and a second middle portion VBPR 130 disposed on first and a second lower portion VBPR 126, respectively, with each middle portion VBPR 130 having a width less than a width of lower portion VBPR 126. The first and second lower portion VBPR 126 are disposed on backside power rail 152. FIG. 14D further shows top portion VBPR 136 disposed on a portion of a sidewall of respective source/drain regions 114a and 114b which are disposed on both sides of each respective middle portion VBPR 130 and being separated from middle portion VBPR 130 by self-aligned dielectric spacer 128. In illustrative embodiments, source/drain regions 114a are an n-type region and source/drain regions 114b are a p-type region. FIG. 14D further shows source/drain regions 114a and 114b disposed on backside ILD layer 150.

The power signals can be routed through a backside power delivery network 154 of metal lines coupled to the semiconductor structure to provide power to a number of semiconductor devices. Backside power delivery network 154 is formed over the structure including backside power rails 152 and is based on creation of a wiring scheme that is disposed on both sides of the device layer (front end of line structure).

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first via-to-backside power rail having a lower portion and an upper portion, the lower portion being connected to a first backside power rail and having a first width and the upper portion having a second width less than the first width.

2. The semiconductor structure of claim 1, wherein the lower portion of the first via-to-backside power rail is disposed in an interlevel dielectric layer.

3. The semiconductor structure of claim 2, further comprising a first source/drain region and a second source/drain region disposed on the interlevel dielectric layer;
wherein the upper portion of the first via-to-backside power rail is disposed between the first source/drain region and the second source/drain region.

4. The semiconductor structure of claim 3, further comprising a first self-aligned spacer separating the upper portion of the first via-to-backside power rail from the first source/drain region and the second source/drain region.

5. The semiconductor structure of claim 4, further comprising:
a second backside power rail; and
a second via-to-backside power rail having a lower portion and an upper portion, the lower portion being connected to the second backside power rail and having a first width and the upper portion having a second width less than the first width.

6. The semiconductor structure of claim 5, wherein the lower portion of the second via-to-backside power rail is disposed in the interlevel dielectric layer.

7. The semiconductor structure of claim 6 further comprising a third source/drain region and a fourth source/drain region disposed on the interlevel dielectric layer;
wherein the upper portion of the second via-to-backside power rail is disposed between the third source/drain region and the fourth source/drain region.

8. The semiconductor structure of claim 7, further comprising a second self-aligned spacer separating the upper portion of the second via-to-backside power rail from the third source/drain region and the fourth source/drain region.

9. The semiconductor structure of claim 8, wherein the first source/drain region and the second source/drain region are an n-type region and the third source/drain region and the fourth source/drain region a p-type region.

10. A semiconductor structure, comprising:
a first via-to-backside power rail having a lower portion, a middle portion and an upper portion, the lower portion disposed in an interlevel dielectric layer;
a first backside power rail connected to the lower portion of the first via-to-backside power rail; and
a first source/drain region and a second source/drain region disposed on the interlevel dielectric layer;
wherein the lower portion has a first width and the middle portion has a second width less than the first width;
wherein the middle portion is disposed between the first source/drain region and the second source/drain region; and
wherein the upper portion is disposed on a portion of a sidewall of the first source/drain region to connect the middle portion to the first source/drain region.

11. The semiconductor structure of claim 10, further comprising:
a first self-aligned spacer disposed on the remaining portion of the sidewall of the first source/drain region, wherein the first self-aligned spacer and the upper portion of the first via-to-backside power rail separate the middle portion of the first via-to-backside power rail from the first source/drain region; and
a second self-aligned spacer disposed on a sidewall of the second source/drain region to separate the middle portion of the first via-to-backside power rail from the second source/drain region.

12. The semiconductor structure of claim 11, further comprising:
a first source/drain contact disposed on the first source/drain region and upper portion of the first via-to-backside power rail; and
a second source/drain contact disposed on the second source/drain region.

13. The semiconductor structure of claim 12, further comprising:
a second via-to-backside power rail having a lower portion, a middle portion and an upper portion, the lower portion disposed in the interlevel dielectric layer;
a second backside power rail connected to the lower portion of the second via-to-backside power rail; and
a third source/drain region and a fourth source/drain region disposed on the interlevel dielectric layer;
wherein the lower portion of the second via-to-backside power rail has a first width and the middle portion of the second via-to-backside power rail has a second width less than the first width;
wherein the middle portion of the second via-to-backside power rail is disposed between the third source/drain region and the fourth source/drain region; and
wherein the upper portion of the second via-to-backside power rail is disposed on a portion of a sidewall of the third source/drain region to connect the middle portion of the second via-to-backside power rail to the third source/drain region.

14. The semiconductor structure of claim 13, further comprising:
a third self-aligned spacer disposed on the remaining portion of the sidewall of the third source/drain region, wherein the third self-aligned spacer and the upper portion of the second via-to-backside power rail separate the middle portion of the second via-to-backside power rail from the third source/drain region; and
a fourth self-aligned spacer disposed on a sidewall of the fourth source/drain region to separate the middle portion of the second via-to-backside power rail from the fourth source/drain region.

15. The semiconductor structure of claim 14, further comprising:
a third source/drain contact disposed on the third source/drain region and upper portion of the second via-to-backside power rail; and
a fourth source/drain contact disposed on the fourth source/drain region.

16. The semiconductor structure of claim 15, further comprising a frontside back-end-of-line interconnect disposed on the first source/drain contact, the second source/drain contact, the third source/drain contact and the fourth source/drain contact.

17. A semiconductor structure, comprising:
a via-to-backside power rail having a lower portion and an upper portion, the lower portion being connected to a backside power rail and having a first width and the upper portion having a second width less than the first width; and
a middle-of-the-line contact disposed on the upper portion of the via-to-backside power rail.

18. The semiconductor structure of claim 17, further comprising a self-aligned spacer disposed on sidewalls of the upper portion of the via-to-backside power rail and the middle-of-the-line contact.

19. The semiconductor structure of claim 18, further comprising a dielectric pillar disposed on sidewalls of the self-aligned spacer.

20. The semiconductor structure of claim 17, further comprising a frontside back-end-of-line interconnect disposed on the middle-of-the-line contact.
